(19) United States
(12) Patent Application Publication
(10) Pub. No.: US 2002/0050626 A1
(43) Pub. Date: May 2, 2002

(54) Semiconductor device and manufacturing method therefor

(76) Inventors: Norihiro Onuma, Kanagawa (JP); Katsuji Matsumoto, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/907,026

(22) Filed: Jul. 17, 2001

(30) Foreign Application Priority Data
Jul. 19, 2000 (JP) P2000-223879

(51) Int. Cl. H01L 21/00; H01L 21/20; H01L 29/00

(52) U.S. Cl. 257/531; 438/381

(57) ABSTRACT

A semiconductor device and a manufacturing method for the same achieve higher performance of an inductance element and also reduce contamination. The semiconductor device includes a second layer wire spirally formed and deposited, through the intermediary of an interlayer dielectric, on a first layer wire formed on a semiconductor substrate through the intermediary of an insulating layer, a protective film that is deposited on the second layer wire and has an opening in a portion corresponding to a region surrounded by the second layer wire, and a ferromagnetic member provided in the opening.

### BACKGROUND OF THE INVENTION

1. Field of the Invention

The present invention relates to a semiconductor device and a manufacturing method for the same and, more particularly, to a structure of an inductance element formed on a semiconductor substrate.

2. Description of the Related Art

In a semiconductor device, such as a large-scale integrated circuit (LSI), the recent trend toward higher frequencies has been accelerating the need for adding an inductance element onto an LSI, whereas the inductance element has not conventionally been mounted on an LSI. FIG. 6 shows the configuration of an example of a typical semiconductor device having an inductance element. With reference to FIG. 6, a semiconductor device 1 will be described.

The semiconductor device 1 is mainly provided with a substrate 2, a first layer wire 3, an interlayer dielectric 4, and a second layer wire 5. On the substrate 2, the first layer wire 3 is deposited in a predetermined pattern via an insulating layer 2a, and the interlayer dielectric 4 is deposited on the first layer wire 3. The second layer wire 5 is spirally formed on the interlayer dielectric 4 to provide a spiral inductance element. Furthermore, a contact hole 4a is formed in the interlayer dielectric 4, and an electric conductor is placed in the contact hole 4a thereby to electrically connect the first layer wire 3 and the second layer wire 5.

Unlike a semi-insulating substrate of gallium arsenide or the like, a silicon substrate is electrically conductive; therefore, when an inductance element is mounted on an LSI, mutual inducing phenomenon is prone to occur between the inductance element and the silicon substrate. This causes an energy loss due to eddy current, posing a problem in that it is difficult to obtain desired characteristics. There is another problem in that securing desired inductance value and Q value requires an extremely large area, resulting in lower integration.

As solutions to the problems described above, there have been proposed methods typically represented by the one disclosed in, for example, Japanese Unexamined Patent Publication No. 9-186291, wherein an insulating film used with a semiconductor device contains a ferromagnetic material. To be more specific, in a semiconductor device 1a shown in FIG. 7, a second layer wire 5 that is spirally shaped is formed on a semiconductor substrate 2 via an insulating layer 2a. A first layer wire 3 is formed on the second layer wire 5 via the interlayer dielectric 4. An insulating film 7 containing a ferromagnetic material is formed between the first layer wire 3 and the interlayer dielectric 4.

The ferromagnetic material for the insulating film shown in FIG. 7 is added during a wiring process in the manufacture of semiconductors. It is difficult, however, to introduce a ferromagnetic material, such as Fe, Co, or Ni, during the process because of the processing of the ferromagnetic material and also of the possibility of contamination in a semiconductor manufacturing apparatus. More specifically, there is likelihood of contamination of the semiconductor devices by the ferromagnetic materials in the semiconductor manufacturing apparatus during a sputtering process or the like for forming the insulating film 7 containing a ferromagnetic material.

The above difficulty applies when an insulative material (photosensitive polyimide or SOG) containing a powdery ferromagnetic material is used. Functionally, the use of such ferromagnetic materials is disadvantageous in improving the characteristics of the semiconductor device 1a, as compared with a case where only a ferromagnetic member is used.

Furthermore, in the semiconductor device 1a shown in FIG. 7, the second layer wire 5 making up a spiral inductance element is formed near the semiconductor substrate 2, and the first layer wire 3 serving as an outgoing electrode is formed on the top. However, forming the inductance element by the wiring layer near the semiconductor substrate 2 is not desirable from the viewpoint of parasitic capacitance. In addition, it is not desirable to form the second layer wire 5 near the semiconductor substrate 2 in the semiconductor device 1 or 1a from the viewpoint of parasitic resistance, because the thickness of a wiring film can be increased in a higher layer.

### SUMMARY OF THE INVENTION

Accordingly, the present invention has been made with a view toward solving the above problems, and it is an object of the present invention to provide a semiconductor device and a manufacturing method for the same that are capable of achieving an inductance element with higher performance and reducing contamination.

To this end, according to one aspect of the present invention, there is provided a semiconductor device equipped with a second layer wire spirally formed and deposited, through the intermediary of an interlayer dielectric, on a first layer wire formed on a semiconductor substrate through the intermediary of an insulating layer, the semiconductor device further including a protective film that is deposited on the second layer wire and has an opening in a portion corresponding to a region surrounded by the second layer wire, and a ferromagnetic member provided in the opening.

In this arrangement, the first layer wire is formed on the semiconductor substrate through the intermediary of the insulating layer, and the spiral second layer wire is formed on the first layer wire through the intermediary of the interlayer dielectric. The protective film having the opening is deposited on the second layer wire, and the ferromagnetic member is inserted in the opening. The opening is formed in the portion that corresponds to the region surrounded by the second layer wire that has been spirally formed. Thus, placing the ferromagnetic member in the opening rather than forming an insulating film that contains a ferromagnetic material in the vicinity of the second layer wire makes it possible to improve the characteristics of an inductance element and to reduce contamination at the same time.

The first wire layer is formed in a portion adjacent to the semiconductor substrate, and the second layer wire constituting a spiral inductance element is formed on the first wire layer through the intermediary of the interlayer dielectric. With this arrangement, the parasitic capacitance attributable to the second layer wire can be reduced, and the film thickness of the second layer wire can be increased, allowing reduced parasitic resistance to be achieved.

According to another aspect of the present invention, there is provided a manufacturing method for a semiconductor device including the steps of forming a first layer wire on a semiconductor substrate through the intermediary of an insulating layer, forming a spiral second layer wire on the first layer wire through the intermediary of an interlayer dielectric, forming a protective layer on the second layer wire, forming an opening in the protective layer at a portion corresponding to a region surrounded by the second layer wire, and providing a ferromagnetic member composed of a ferromagnetic material in the opening.

Thus, the ferromagnetic member for achieving higher performance of the inductance element is not handled during a wiring step of a manufacturing process of a semiconductor device, making it possible to protect a semiconductor manufacturing apparatus from contamination attributable to a ferromagnetic material. Moreover, since the ferromagnetic member is provided after the protective film is deposited on the second layer wire, the occurrence of contamination caused by forming the ferromagnetic member can be restrained.

In addition, the first layer wire is formed in the vicinity of the semiconductor substrate, and the second layer wire making up the spiral inductance element is formed on the first layer wire through the intermediary of the interlayer dielectric. With this arrangement, the parasitic capacitance attributable to the second layer wire can be reduced, and the film thickness of the second layer wire can be increased, so that the parasitic resistance can be also reduced.

### BRIEF DESCRIPTION OF THE DRAWINGS

FIG. 1 shows the configuration of a preferred embodiment of a semiconductor device in accordance with the present invention;

FIG. 2 shows a process of a preferred embodiment of a manufacturing method for a semiconductor device in accordance with the present invention;

FIG. 3 shows the process of the preferred embodiment of the manufacturing method for a semiconductor device in accordance with the present invention;

FIG. 4 is a cross-sectional view showing another embodiment of the semiconductor device in accordance with the present invention;

FIG. 5 is a cross-sectional view showing still another embodiment of the semiconductor device in accordance with the present invention;

FIG. 6 shows the configuration of an example of a conventional semiconductor device; and

FIG. 7 shows a configuration of another example of a conventional semiconductor device.

### DESCRIPTION OF THE PREFERRED EMBODIMENTS

A preferred embodiment in accordance with the present invention will now be described in detail with reference to the accompanying drawings.

The following embodiment is a preferred specific example of the present invention, and various preferred technological restrictions will be added. The scope of the present invention, however, is not limited to the modes described below unless otherwise particularly specified.

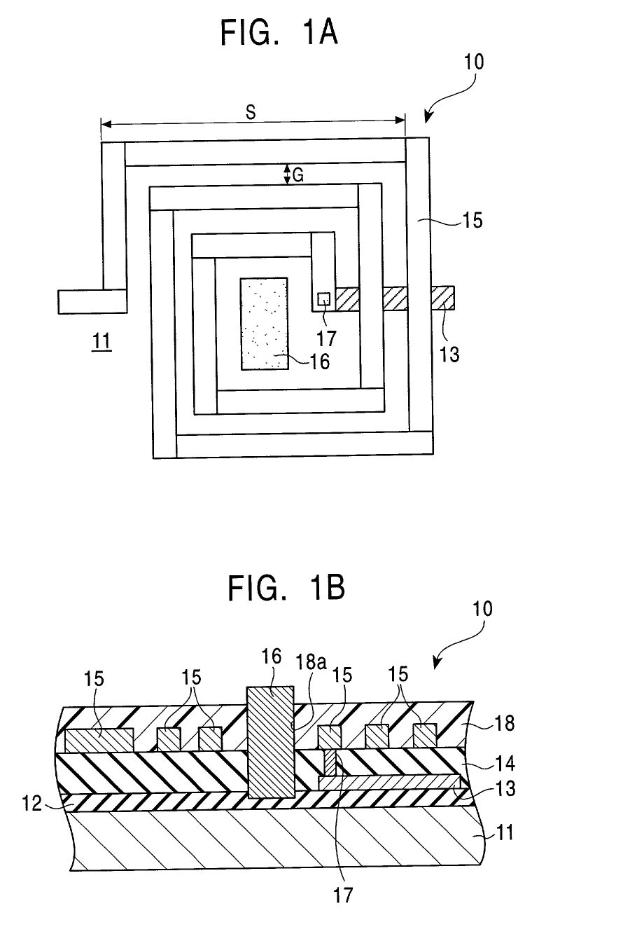

FIG. 1 shows the configuration of a preferred embodiment of a semiconductor device in accordance with the present invention. Referring to FIG. 1, a semiconductor device 10 will be explained.

The semiconductor device 10 shown in FIG. 1 primarily includes a semiconductor substrate 11, an insulating layer 12, a first layer wire 13, an interlayer dielectric 14, a second layer wire 15, a ferromagnetic member 16, and a passivation layer (passivation film) 18 serving as a protective layer.

Referring to FIG. 1B, the insulating layer 12 is deposited on the semiconductor substrate 11 with an LSI thereon, and the first layer wire 13, which is a outgoing wire of the second layer wire 15, is deposited on the insulating layer 12.

The second layer wire 15 is formed on the first layer wire 13 through the intermediary of the interlayer dielectric 14. A contact hole 17 is formed in the interlayer dielectric 14, and an electric conductor, such as a tungsten plug, is placed in the contact hole 17 thereby to electrically connect the first layer wire 14 and the second layer wire 15.

The second layer wire 15 shown in FIG. 1A constitutes a spiral inductance element substantially formed into a square spiral shape. The inductance value of the second layer wire 15 is given by the expression shown below.

[Expression 1]

Inductance of spiral inductance element

L(TOTAL)=L+2M+L≅8L(1PATH)+8M(1PATH)

Thus, the inductance value is represented by the sum of the self inductance value L (1PATH) of the wire and the inter-wire mutual inductance value M (1PATH). In the inductance value of the spiral inductance element, the mutual inductance value M (1PATH) is dominant.

At this time, the self inductance value L (1PATH) per wire is given by the expression shown below.

[Expression 2]

Self inductance per wire

$$L ( 1 PATH ) = 2 \times {10}^{- 4} \times S \times \{ ln ( \frac{2 S}{W + T} ) + 0.5 \}$$

where S denotes the length of the wire, W denotes the width of the second layer wire 15, and T denotes the thickness of the second layer wire 15.

If the gap between wires is denoted as G and the permeability of vacuum is denoted as μ₀, then the inter-wire mutual inductance value M (1PATH) is given by the expression shown below.

[Expression 3]

Mutual inductance between wires having a length of S and being spaced away by a distance G

$$M ( 1 PATH ) = \frac{{µ}_{0}}{2 π} \{ G - \sqrt{{S}^{2} + {G}^{2}} + S ln ( \frac{\sqrt{{S}^{2} + {G}^{2}} + S}{G} ) \}$$

If S>>G, then

$$\begin{matrix}= \frac{{µ}_{0} S }{2 π} \{ \frac{G}{S} - \sqrt{1 + {( \frac{G}{S} )}^{2}} + ln ( \sqrt{1 + {( \frac{S}{G} )}^{2}} + ( \frac{S}{G} ) ) \} \\ = \frac{{µ}_{0} S }{2 π} ( \frac{G}{S} + ln ( \frac{2 S}{G} - 1 ) ) \\ = \frac{{µ}_{0} S }{2 π} ( ln \frac{2 S}{G} - 1 )\end{matrix}$$

The self inductance value L (1PATH) and the mutual inductance value M (1PATH) are both proportional to the length S of the wires. In order to form the second layer wire 15 into an efficient inductance element, it is desirable to expand the area by increasing the length S of one side of the spiral, forming a spiral of about two turns, for example.

The passivation layer 18 for protecting the second layer wire 15 is deposited on the second layer wire 15. In the passivation layer 18, an opening 18a is formed in a portion that corresponds to the region surrounded by the second layer wire 15. The opening 18a is formed so as to extend, for example, from the passivation layer 18 to the interlayer dielectric 14 or the insulating layer 12. This makes it possible to provide the ferromagnetic member 16 in the vicinity of the semiconductor substrate 11.

The ferromagnetic member 16 is inserted in the opening 18a. More specifically, the opening 18a is formed in a portion that is surrounded by the spiral second layer wire 15 and does not have a wiring pattern. Hence, the ferromagnetic member 16 is provided in the region surrounded by the second layer wire 15. The ferromagnetic member 16 is composed of, for example, Fe, Co, or Ni, and is formed to have a configuration substantially identical to that of the opening 18a, and inserted in the opening 18a.

The inductance value of the spiral inductance element composed of the second layer wire 15 is proportional to the permeability of the material surrounding the spiral inductance element. Thus, the ferromagnetic member 16 formed in the peripheral portion of the second layer wire 15 enables an improved inductance value to be achieved. To be more specific, the permeability μ of the ferromagnetic material Fe is 200 to 300 times the permeability μ of SiO₂, so that the inductance value can be dramatically improved. Moreover, since the ferromagnetic member 16 formed of the ferromagnetic material is inserted in the opening 18a, the characteristics of the inductance element can be improved, as compared with the case where the ferromagnetic member 16 is formed using an insulating film that contains a ferromagnetic material.

In addition, to form the ferromagnetic member 16 on the semiconductor device 10, the ferromagnetic member 16 is inserted in the opening 18a that has been formed in advance rather than forming a ferromagnetic member film or the like in an earlier step of the manufacturing process for a semiconductor device, as in the conventional manufacturing method. Therefore, a semiconductor manufacturing apparatus can be protected from contamination by a ferromagnetic material.

The first layer wire 13, which is an outgoing wire, is formed on the side of the semiconductor substrate 11, and the second layer wire 15 constituting the spiral inductance element is formed above the first layer wire 13 thereby to permit reduced parasitic capacitance of the second layer wire 15. Furthermore, the film thickness can be increased in higher layers, so that the second layer wire 15 can be made thicker thereby to permit reduced parasitic resistance.

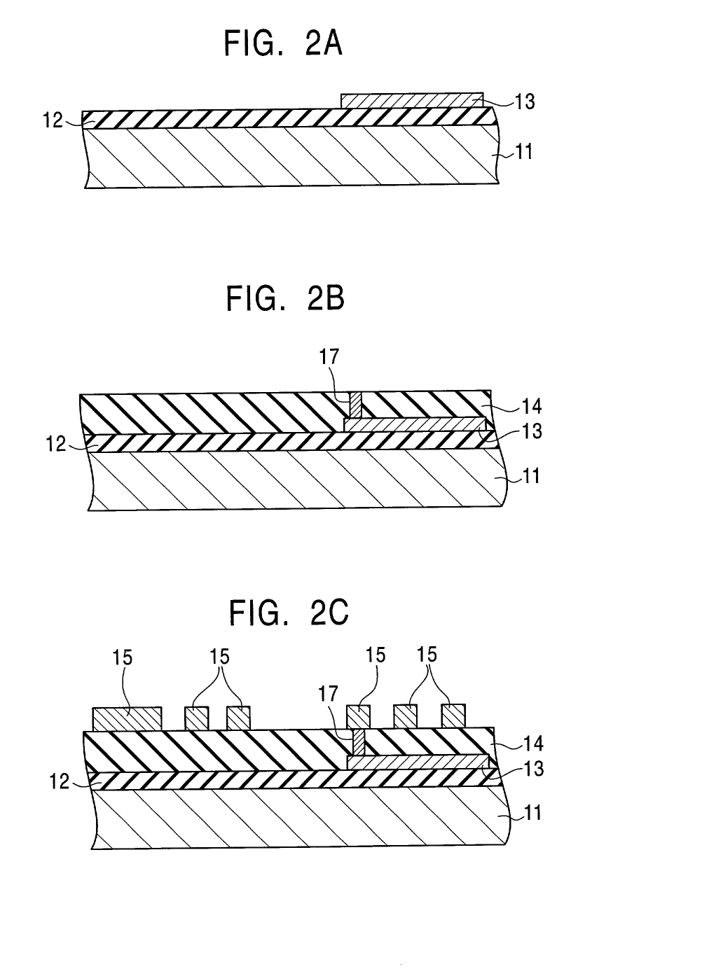

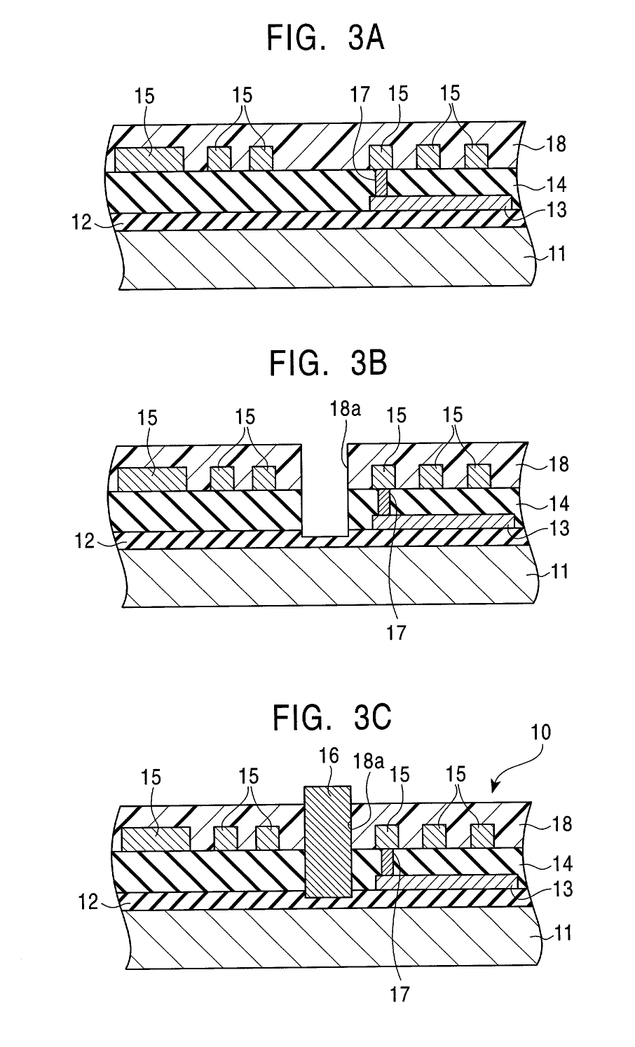

FIG. 2 and FIG. 3 show the process steps of a preferred embodiment of a manufacturing method for a semiconductor device in accordance with the present invention. The manufacturing method for a semiconductor device will now be described with reference to FIG. 2 and FIG. 3.

Referring first to FIG. 2A, a passive element and an active element, etc. are formed by, for example, photolithography or the like, on the semiconductor substrate 11 composed of silicon, gallium, or the like.

Thereafter, the insulating layer 12 is formed on the substrate 11, and the first layer wire 13 is formed on the insulating layer 12 according to a predetermined pattern. At the same time, the wiring for connecting the elements formed on the semiconductor substrate 11 is also performed. Then, the first layer wire 13 is planarized, and the interlayer dielectric 14 is formed on the planarized first layer wire 13.

Subsequently, as shown in FIG. 2B, the contact hole 17 is formed in the interlayer dielectric 14 on the first layer wire 13, and an electric conductor, such as a tungsten plug or the like, is inserted in the contact hole 17.

In the succeeding step, an electrically conductive film is formed on the interlayer dielectric 14 into a spiral configuration by photolithography or the like to produce the second layer wire 15, as shown in FIG. 2C. At this time, the second layer wire 15 is formed into a spiral of, for example, two turns.

Thereafter, the passivation layer 18 is deposited on the second layer wire 15, as shown in FIG. 3A.

Then, as shown in FIG. 3B, the opening 18a is formed in the region surrounded by the spiral second layer wire 15 by dry etching (RIE) or the like using, for example, an ion milling apparatus. At this time, the opening 18a is formed such that it penetrates, for example, the passivation layer 18 and the interlayer dielectric 14 and reaches the insulating layer 12, but does not reach the substrate 11. If, however, the opening 18a reaches the substrate 11, another passivation film composed of a nitride film or the like may be formed after the opening 18a is formed, thereby providing electrical insulation between the substrate 11 and the ferromagnetic member 16. Thus, the ferromagnetic member 16 can be provided in the vicinity of the semiconductor substrate 11.

After that, as illustrated in FIG. 3C, the ferromagnetic member 16 that has been formed by a micromachine or the like to have substantially the same size as that of the opening 18a is inserted in the opening 18a from above the passivation layer 18. Thereafter, wiring and molding are carried out to complete the semiconductor device 10.

Thus, to provide the ferromagnetic member 16 in the peripheral area of the second layer wire 15 constituting the spiral inductance element, the ferromagnetic member 16 is placed in the opening 18a rather than forming an insulating film that has a ferromagnet in a wire forming step of the manufacturing process for a semiconductor device. Therefore, the contamination by a ferromagnetic material during a semiconductor device manufacturing process can be restrained.

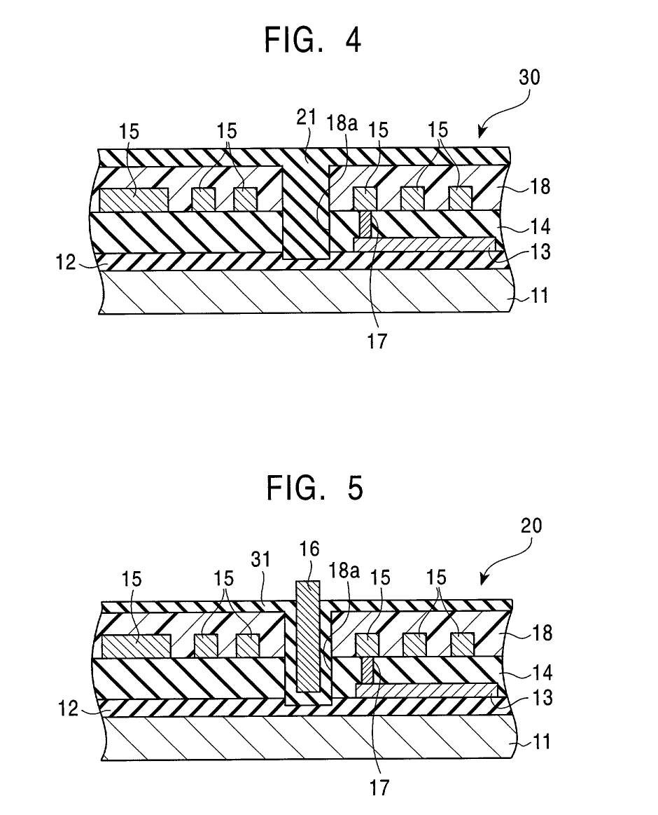

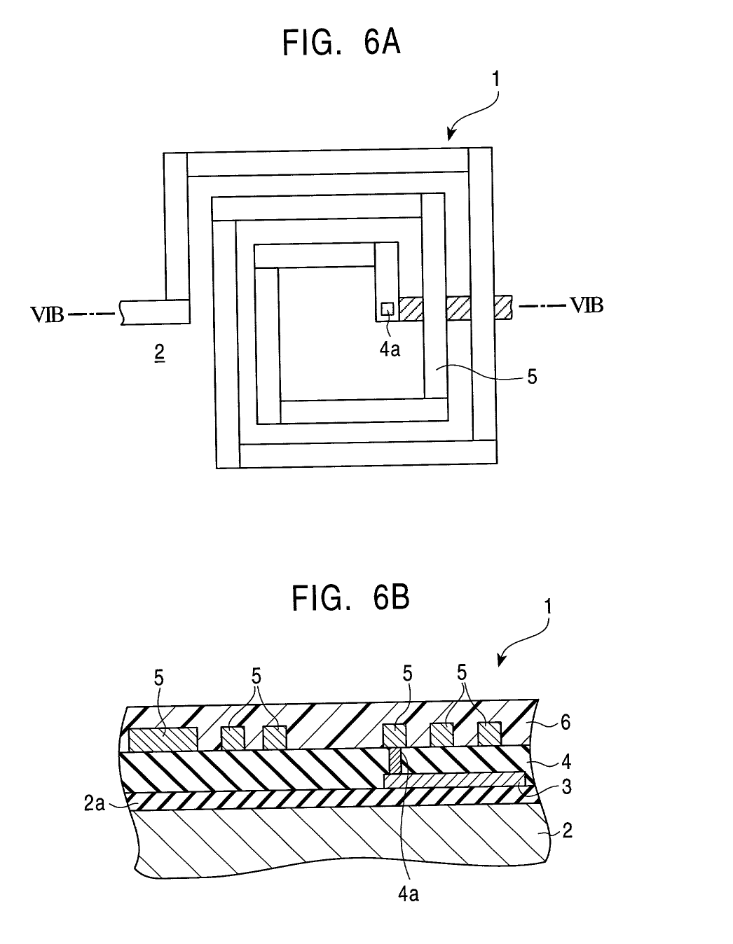

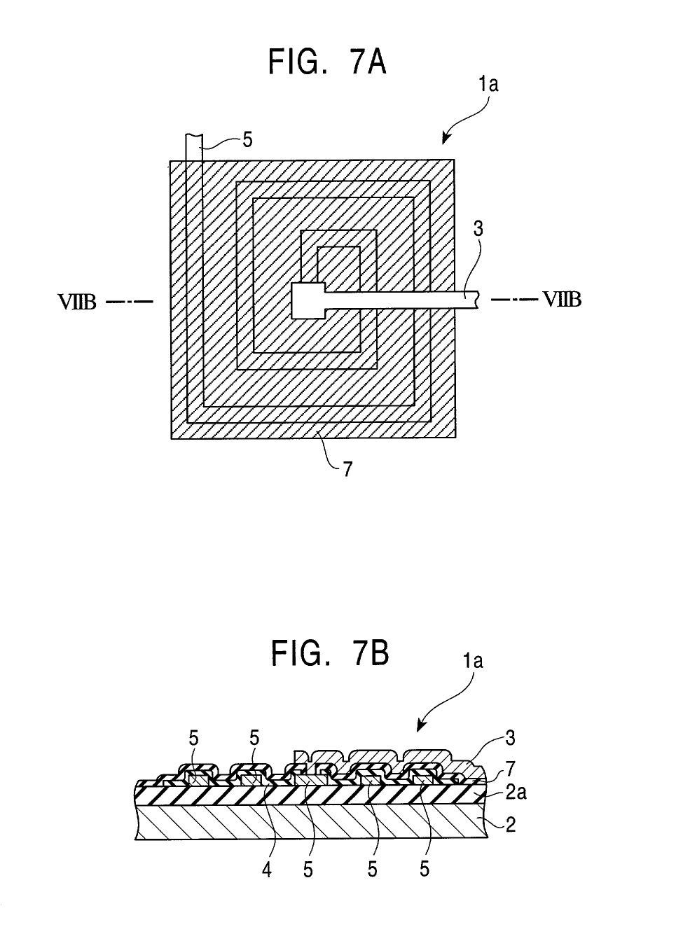

As an alternative to the step of inserting the ferromagnetic member 16 in the opening 18a shown in FIG. 3C, the opening 18a may be formed, then an insulating film (a ferromagnetic member) 21 composed of polyimide or spin on glass (SOG), an organic coating film, that contains a ferromagnetic material may be applied onto the passivation layer 18, as shown in FIG. 4. The insulating film 21 formed on the top surface of the passivation layer 18 may be selectively removed so that the insulating film 21 remains only on the region where the second layer wire 15 has been formed.

As another alternative, after the opening 18a is formed, an insulating film 31 composed of a nitride film or the like that does not allow impurities to permeate therethrough may be formed on the opening 18a and the passivation layer 18, then the insulating film 21 may be applied to the opening 18a, or the ferromagnetic member 16 may be inserted in the opening 18a, as shown in FIG. 5. This arrangement makes it possible to restrain the influences exerted on the semiconductor device 10 by the impurities contained in the ferromagnetic member 16, thereby restraining the contamination.

Thus, the embodiment described above solves the problem of contamination that may occur due to the introduction of the ferromagnetic member 16 as a high-performance inductance element in an early stage of the manufacturing process of, for example, a high-frequency semiconductor device.

Moreover, the ferromagnetic member 16 can be inserted as far as immediately above the semiconductor substrate 11 or in the semiconductor substrate 11. This allows the characteristics (inductance value and Q value) of the inductance element to be improved without the need for increasing the size of the semiconductor device 10. The result is the semiconductor device 10 featuring good high-frequency characteristics.

Furthermore, improved characteristics can be achieved by the use of a ferromagnetic material, and the topmost layer wire can be used as an inductor forming layer (the second layer wire 15) at the same time. The present invention, therefore, is ideally suited for manufacturing the high-frequency, VLSI semiconductor device 10 that requires a high-performance inductance element.

The present invention is not limited to the embodiment described above.

For instance, the second layer wire 15 is formed of the planar spiral inductor that is a substantially square spiral; however, the second layer wire 15 may alternatively be formed of a multi-inductor or a meandering inductor.

Thus, the present invention makes it possible to achieve higher performance of an inductance element and to provide a semiconductor device and a manufacturing method for the same that restrain contamination.

What is claimed is:

1. A semiconductor device comprising:
a second layer wire spirally formed and deposited, through the intermediary of an interlayer dielectric, on a first layer wire formed on a semiconductor substrate through the intermediary of an insulating layer;
a protective film that is deposited on the second layer wire and has an opening in a portion corresponding to a region surrounded by the second layer wire; and
a ferromagnetic member that is composed of a ferromagnetic material and provided in the opening.

2. A semiconductor device according to claim 1, wherein the ferromagnetic member is composed of an insulating film that contains a ferromagnetic material.

3. A semiconductor device according to claim 1, wherein the ferromagnetic member is composed of a ferromagnetic material having a configuration substantially identical to that of the opening.

4. A semiconductor device according to claim 1, wherein the opening is formed so that it extends from the protective film to the interlayer dielectric.

5. A semiconductor device according to claim 1, wherein an insulating film having the ferromagnetic material is deposited on the protective film.

6. A manufacturing method for a semiconductor device comprising the steps of:
forming a first layer wire on a semiconductor substrate through the intermediary of an insulating layer;
forming a spiral second layer wire on the first layer wire through the intermediary of an interlayer dielectric;
forming a protective layer on the second layer wire;
forming an opening in the protective layer at a portion corresponding to a region surrounded by the second layer wire; and
providing a ferromagnetic member composed of a ferromagnetic material in the opening.

7. A manufacturing method for a semiconductor device according to claim 6, wherein an insulating film containing a ferromagnetic material is applied to the opening.

8. A manufacturing method for a semiconductor device according to claim 6, wherein a ferromagnetic member having a configuration substantially identical to that of the opening is inserted in the opening.

9. A manufacturing method for a semiconductor device according to claim 6, wherein the opening is formed so that it extends from the protective layer to the interlayer dielectric.

10. A manufacturing method for a semiconductor device according to claim 6, wherein the ferromagnetic member is applied also onto the protective film when providing the ferromagnetic member in the opening.
